(19) United States
(12) Patent Application Publication
(10) Pub. No.: US 2023/0263065 A1
(43) Pub. Date: Aug. 17, 2023

(54) PIEZOELECTRIC ELEMENT AND MEMS MIRROR

(71) Applicant: Panasonic Intellectual Property Management Co., Ltd., Osaka (JP)

(72) Inventor: Takakiyo HARIGAI, Kyoto (JP)

(21) Appl. No.: 18/139,834

(22) Filed: Apr. 26, 2023

Related U.S. Application Data
(63) Continuation of application No. PCT/JP2021/026937, filed on Jul. 19, 2021.

(30) Foreign Application Priority Data
Oct. 28, 2020 (JP) 2020-180796

(51) Int. Cl. H10N 30/853; B81B 3/00; G02B 26/08

(52) U.S. Cl. CPC H10N 30/8548; B81B 3/0021; G02B 26/0858; B81B 2201/042

(57) ABSTRACT

A piezoelectric element includes a lower electrode layer, an upper electrode layer, an orientation control layer disposed between the lower electrode layer and the upper electrode layer, and a piezoelectric layer formed on an upper surface of the orientation control layer. The piezoelectric layer is oriented in a (001) plane or a (100) plane and has a perovskite structure including Pb(Mg_{1/3}, Nb_{2/3})O₃. The orientation control layer has a perovskite structure, is oriented in the (001) plane or the (100) plane, and contains a part of components forming the piezoelectric layer, as an additive.

### CROSS REFERENCE TO RELATED APPLICATION

This application is a continuation of International Application No. PCT/JP2021/026937 filed on Jul. 19, 2021, entitled “PIEZOELECTRIC ELEMENT AND MEMS MIRROR”, which claims priority under 35 U.S.C. Section 119 of Japanese Patent Application No. 2020-180796 filed on Oct. 28, 2020, entitled “PIEZOELECTRIC ELEMENT AND MEMS MIRROR”. The disclosures of the above applications are incorporated herein by reference.

### BACKGROUND OF THE INVENTION

### Field of the Invention

The present invention relates to a piezoelectric element and a MEMS mirror including the piezoelectric element.

### Description of Related Art

Recently, by using the micro electro mechanical system (MEMS) technology, MEMS mirrors that perform scanning with a laser beam and project an image onto a screen or the like have been developed. A MEMS mirror includes, as a driving means, for example, a piezoelectric element in which electrodes are disposed on both main surfaces of a piezoelectric film.

MEMS mirrors are used in image projection devices such as head-up displays and head-mounted displays as well as in laser radars that use laser beams to detect objects, etc., and are required to have higher driving speeds, larger deflection angles, and larger reflection sizes. Therefore, piezoelectric elements serving as driving sources are also required to have higher piezoelectric constants and higher withstand voltages. Specifically, the absolute value of a piezoelectric constant d31 (hereinafter, simply referred to as “piezoelectric constant d31”) is required to be 120 pm/V or higher. In addition, a withstand voltage is required to be 150 V or higher, and is further preferably 180 V or higher.

As a method for increasing the piezoelectric constant d31 of a piezoelectric element, Japanese Laid-Open Patent Publication No. 2005-333108 describes a method in which an orientation control layer is formed from (Pb, La) (Zr, Ti)O₃ to which Zr, Mg, Mn, or the like is added, and a piezoelectric film is formed from Pb(Zr, Ti)O₃ including Pb(Mg_{1/3}, Nb_{2/3})O₃.

In the piezoelectric element described in Japanese Laid-Open Patent Publication No. 2005-333108, the piezoelectric constant d31 is increased, but the withstand voltage remains low.

### SUMMARY OF THE INVENTION

A first aspect of the present invention is directed to a piezoelectric element. The piezoelectric element according to this aspect includes: a lower electrode layer; an upper electrode layer; an orientation control layer disposed between the lower electrode layer and the upper electrode layer; and a piezoelectric layer formed on an upper surface of the orientation control layer. The piezoelectric layer is oriented in a (001) plane or a (100) plane and has a perovskite structure including Pb(Mg_{1/3}, Nb_{2/3})O₃. The orientation control layer has a perovskite structure, is oriented in the (001) plane or the (100) plane, and contains a part of components forming the piezoelectric layer, as an additive.

In the piezoelectric element according to this aspect, since the orientation control layer contains a part of the components forming the piezoelectric layer as an additive, the orientation of the piezoelectric layer is easily aligned with the (001) plane or the (100) plane in which the orientation control layer is oriented, so that the piezoelectric layer can be more stably oriented in the (001) plane or the (100) plane. Accordingly, the piezoelectric constant d31 and the withstand voltage of the piezoelectric element can be increased.

A second aspect of the present invention is directed to a MEMS mirror. The MEMS mirror according to this aspect includes: the piezoelectric element according to the first aspect; a movable part configured to be movable when the piezoelectric element is driven; and a mirror installed at the movable part.

The MEMS mirror according to this aspect includes the piezoelectric element according to the first aspect having a high piezoelectric constant d31 and withstand voltage, the deflection angle of a mirror when a constant voltage is applied can be increased, and the mirror can be driven at a higher driving voltage. Therefore, the mirror can be driven at a larger deflection angle, and the deflection angle characteristics of the MEMS mirror can be significantly enhanced.

The effects and the significance of the present invention will be further clarified by the description of the embodiment below. However, the embodiment below is merely an example for implementing the present invention. The present invention is not limited by the description of the embodiment below in any way.

### BRIEF DESCRIPTION OF THE DRAWINGS

FIG. 1 is a plan view showing a configuration of a MEMS mirror according to an embodiment;

FIG. 2 is a perspective view showing the operation of the MEMS mirror according to the embodiment;

FIG. 3 is a plan view showing another configuration of the MEMS mirror according to the embodiment;

FIG. 4A is a cross-sectional view schematically showing a configuration of a piezoelectric element formed in the MEMS mirror according to the embodiment;

FIG. 4B is a cross-sectional view schematically showing another configuration of the piezoelectric element formed in the MEMS mirror according to the embodiment; and

FIG. 5 is a table showing configurations of orientation control layers and piezoelectric layers according to Examples 1 to 11 and Comparative Examples 1 and 2 and measurement results thereof.

It should be noted that the drawings are solely for description and do not limit the scope of the present invention by any degree.

### DETAILED DESCRIPTION

Hereinafter, an embodiment of the present invention will be described with reference to the drawings. For convenience, in each drawing, X, Y, and Z axes that are orthogonal to each other are additionally shown. The Z-axis positive direction is the vertical upward direction.

<Mems Mirror>

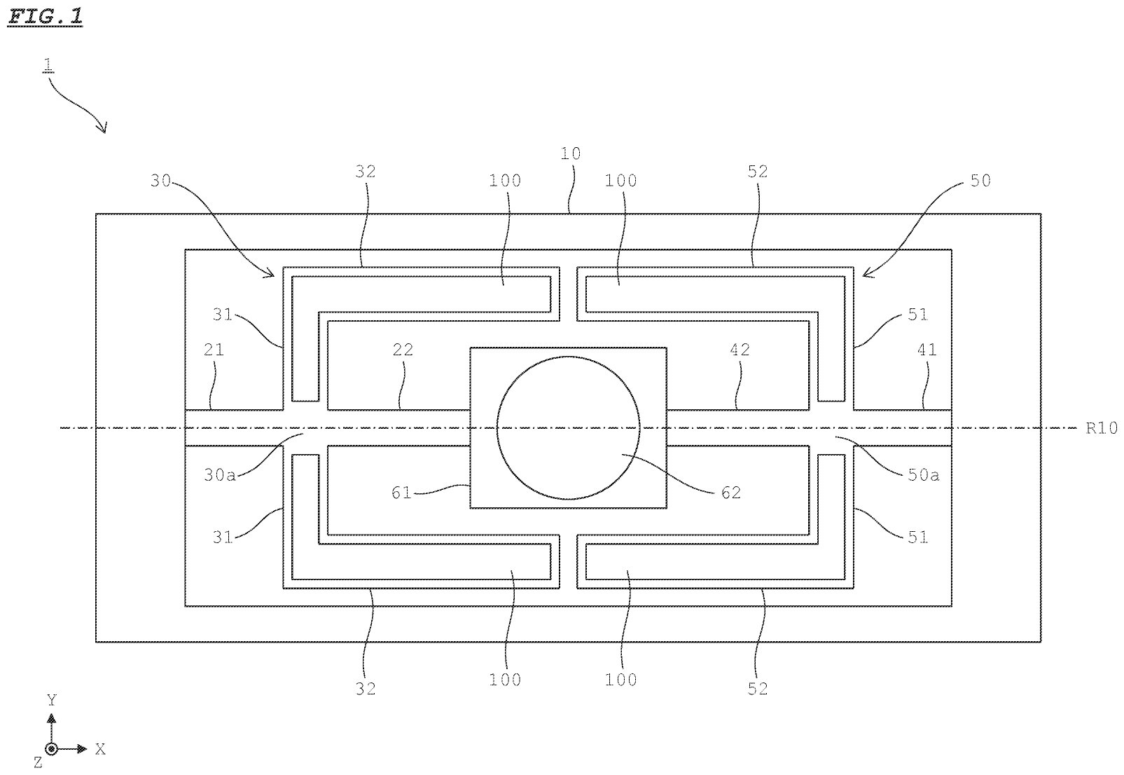

FIG. 1 is a plan view showing a configuration of a MEMS mirror 1.

The MEMS mirror 1 includes a rectangular frame-shaped support 10, two driving beams 21 and 22, a tuning fork vibrator 30, two driving beams 41 and 42, a tuning fork vibrator 50, a movable part 61, a mirror 62, and four piezoelectric elements 100. A rotation center axis R10 passes through the center of the mirror 62 and is parallel to the X-axis direction.

The two driving beams 21 and 22 extend along the rotation center axis R10, and are connected to the X-axis negative side and the X-axis positive side of a vibration center 30a of the tuning fork vibrator 30, respectively. An end portion on the X-axis negative side of the driving beam 21 is connected to the support 10, and an end portion on the X-axis positive side of the driving beam 22 is connected to the movable part 61.

The tuning fork vibrator 30 has a symmetrical configuration with respect to the rotation center axis R10, and includes two coupling parts 31 and two arm parts 32. The two coupling parts 31 extend in the Y-axis direction, and are connected to the Y-axis positive side and the Y-axis negative side of the vibration center 30a, respectively. The other ends of the two coupling parts 31 are connected to end portions on the X-axis negative side of the two arm parts 32, respectively. The two arm parts 32 extend in the X-axis direction.

The two driving beams 41 and 42 also extend along the rotation center axis R10, and are connected to the X-axis positive side and the X-axis negative side of a vibration center 50a of the tuning fork vibrator 50, respectively. An end portion on the X-axis positive side of the driving beam 41 is connected to the support 10, and an end portion on the X-axis negative side of the driving beam 42 is connected to the movable part 61.

The tuning fork vibrator 50 (two coupling parts 51 and two arm parts 52) is configured symmetrically to the tuning fork vibrator 30 (the two coupling parts 31 and the two arm parts 32) with respect to a Y-Z plane passing through the center of the mirror 62 as a plane of symmetry.

The movable part 61 and the mirror 62 have a symmetrical configuration with respect to the rotation center axis R10. The movable part 61 has a flat plate shape. The mirror 62 is installed on a surface on the Z-axis positive side of the movable part 61.

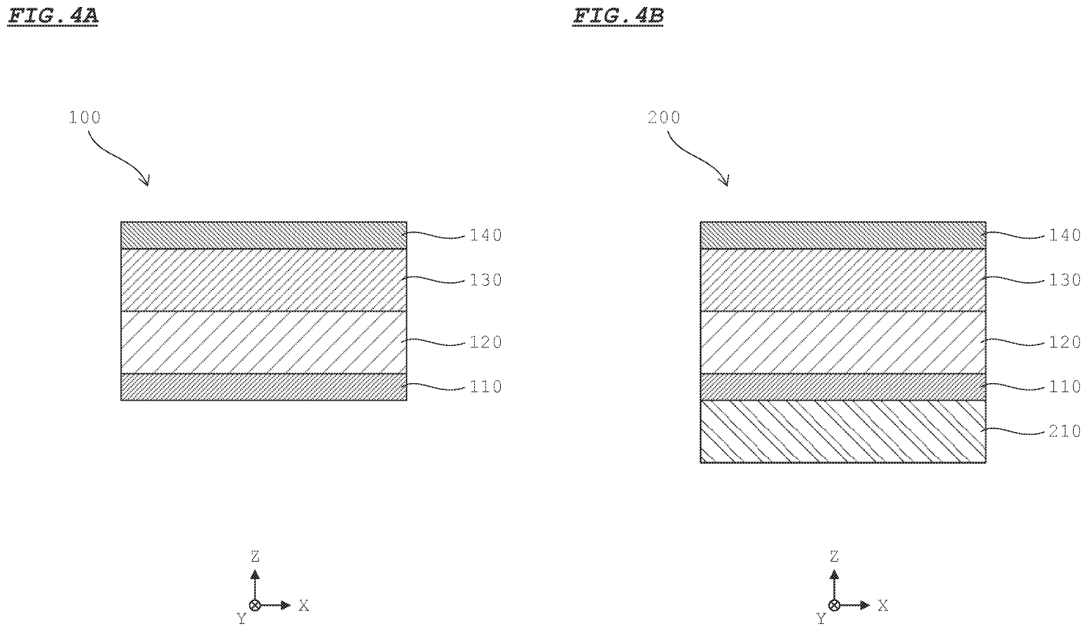

The piezoelectric elements 100 are formed on surfaces on the Z-axis positive side of two pairs of the coupling parts 31 and the arm parts 32 and two pairs of the coupling parts 51 and the arm parts 52, respectively. Each piezoelectric element 100 has an L-shape extending on the coupling part and the arm part. When a voltage is applied to the piezoelectric element 100, the piezoelectric element 100 vibrates the portion (the coupling part and the arm part) on which the piezoelectric element 100 is disposed. The configuration of the piezoelectric element 100 will be described with reference to FIG. 4A later.

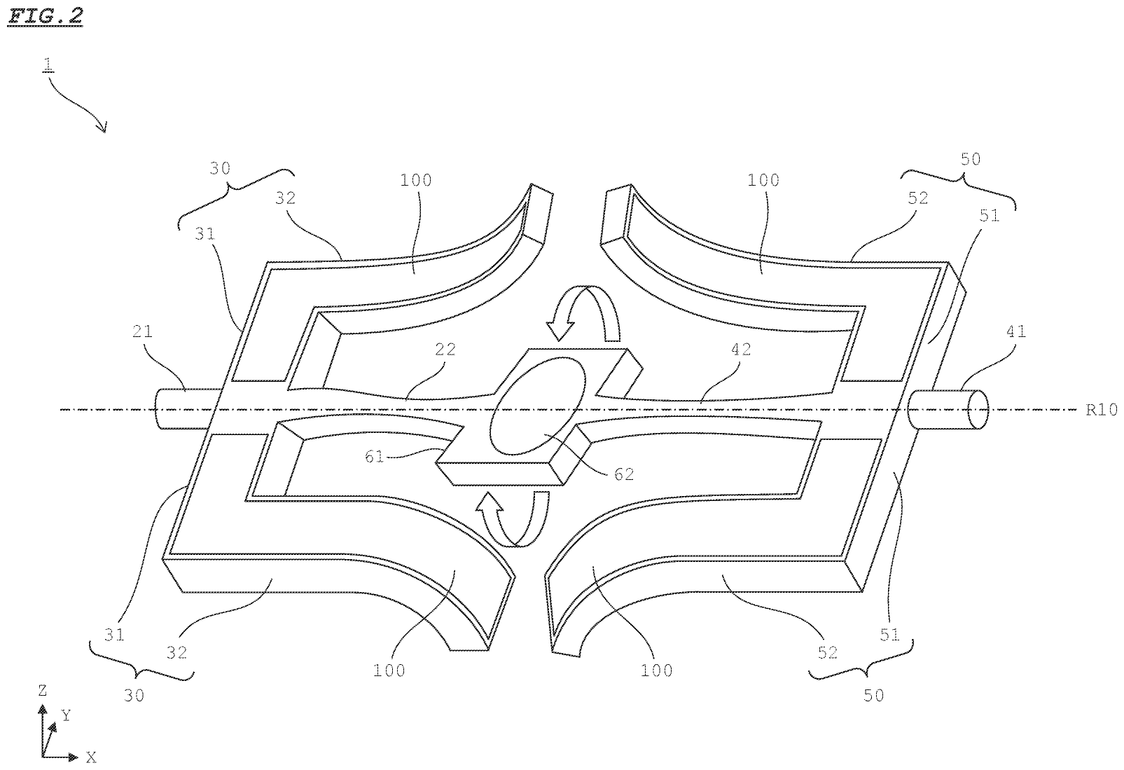

FIG. 2 is a perspective view showing the operation of the MEMS mirror 1. In FIG. 2, for convenience, the support 10 is not shown.

A voltage is applied to each of the four piezoelectric elements 100 such that the arm parts 32 and 52 that face each other in the X-axis direction bend in the same direction, the two arm parts 32 of the tuning fork vibrator 30 bend in opposite directions, and the two arm parts 52 of the tuning fork vibrator 50 bend in opposite directions. The vibrational energy of the tuning fork vibrators 30 and 50 produces torsional vibrations in a vibrator composed of the driving beams 22 and 42 and the movable part 61. Accordingly, the movable part 61 and the mirror 62 repeatedly rotationally vibrate around the rotation center axis R10.

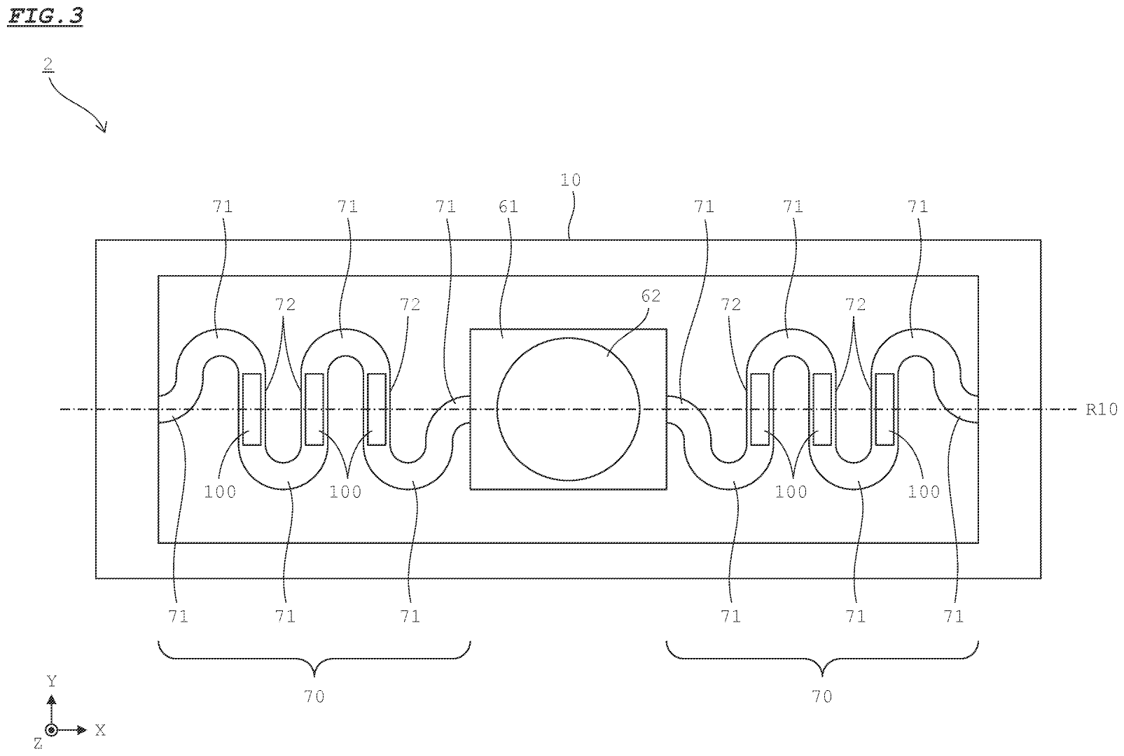

The configuration for causing the movable part 61 and the mirror 62 to repeatedly rotationally vibrate is not limited to the configuration shown in FIG. 1, and may be a configuration as in a MEMS mirror 2 in FIG. 3.

FIG. 3 is a plan view showing a configuration of the MEMS mirror 2. In FIG. 3, for convenience, the same components as those in FIG. 1 are denoted by the same reference characters.

Compared to the MEMS mirror 1 in FIG. 1, the MEMS mirror 2 includes two driving beams 70 having a meander shape instead of the driving beams 21, 22, 41, and 42 and the tuning fork vibrators 30 and 50. Inner end portions in the X-axis direction of the two driving beams 70 are connected to the movable part 61. Outer end portions in the X-axis direction of the two driving beams 70 are connected to the support 10. Each driving beam 70 includes a plurality of curved sections 71 and a plurality of vibrating plates 72 which are alternately coupled so as to form a meander shape. The piezoelectric elements 100 are formed on the plurality of vibrating plates 72.

In the MEMS mirror 2 as well, a voltage is applied to each piezoelectric element 100 such that the movable part 61 and the mirror 62 repeatedly rotationally vibrate around the rotation center axis R10. When the voltage is applied to each piezoelectric element 100, the vibrating plate 72 on which the piezoelectric element 100 is formed is deformed so as to be curved in the Z-axis positive direction or the Z-axis negative direction. By making the phases of the voltages applied to the adjacent piezoelectric elements 100 to be opposite phases, the two adjacent vibrating plates 72 are displaced in opposite directions. Accordingly, these displacements are accumulated around the rotation center axis R10, causing the movable part 61 and the mirror 62 to repetitively rotationally vibrate.

<Piezoelectric Element>

FIG. 4A is a cross-sectional view schematically showing a configuration of the piezoelectric element 100 formed in the above MEMS mirror 1 or 2.

The coupling parts 31 and 51 and the arm parts 32 and 52 of the MEMS mirror 1 and the vibrating plates 72 of the MEMS mirror 2 are composed of, for example, silicon (Si) substrates. Each piezoelectric element 100 is formed, for example, on the upper surface of the silicon substrate with an insulator film of SiO₂ or the like therebetween.

The piezoelectric element 100 includes a lower electrode layer 110, an orientation control layer 120 formed on the upper surface of the lower electrode layer 110, a piezoelectric layer 130 formed on the upper surface of the orientation control layer 120, and an upper electrode layer 140 formed on the upper surface of the piezoelectric layer 130.

The lower electrode layer 110 is composed of a metal electrode film. Examples of the material of the lower electrode layer 110 include metals such as platinum (Pt), palladium (Pd), and gold (Au), oxide conductors such as nickel oxide (NiO), ruthenium oxide (RuO₂), iridium oxide (IrO₂), and strontium ruthenate (SrRuO₃), etc. The lower electrode layer 110 is composed of, for example, two or more of these materials. The lower electrode layer 110 preferably has low electrical resistance and high heat resistance. From such a viewpoint, the lower electrode layer 110 is preferably a Pt film.

The orientation control layer 120 has a perovskite structure, is preferentially oriented in a (001) plane or a (100) plane, and contains a part of components forming the piezoelectric layer 130, as an additive. The orientation control layer 120 is formed on the upper surface of the lower electrode layer 110 by a sputtering method. The piezoelectric layer 130 of the present embodiment contains titanium (Ti) and niobium (Nb). The orientation control layer 120 contains at least one of Ti and Nb, which are part of the components forming the piezoelectric layer 130, as an additive. In addition, the perovskite structure of the orientation control layer 120 is PbTiO₃, (Pb, La)TiO₃, (Pb, La, Mg)TiO₃, or LaNiO₃.

The piezoelectric layer 130 is preferentially oriented in the (001) plane or the (100) plane and has a perovskite structure including Pb(Mg_{1/3}, Nb_{2/3})O₃. The perovskite structure of the piezoelectric layer 130 is Pb(Zr, Ti)O₃ or PbTiO₃. Pb(Zr, Ti)O₃ is a composition in the vicinity of a morphotropic phase boundary (MPB). The piezoelectric layer 130 is formed on the upper surface of the orientation control layer 120 by a sputtering method. Since the orientation control layer 120 is preferentially oriented in the (001) plane or the (100) plane, the piezoelectric layer 130, which is formed on the upper surface of the orientation control layer 120, is also preferentially oriented in the (001) plane or the (100) plane.

Here, when the orientation control layer 120 contains a component of the piezoelectric layer 130 as described above, the piezoelectric layer 130 grows from the upper surface of the orientation control layer 120, by the sputtering method, starting from the common component. Accordingly, it is easier for the piezoelectric layer 130 to grow in an orientation along the orientation of the orientation control layer 120. Therefore, the orientation of the piezoelectric layer 130 is easily aligned with the (001) plane or the (100) plane in which the orientation control layer 120 is oriented, so that the piezoelectric layer 130 is more stably oriented in the (001) plane or the (100) plane.

The upper electrode layer 140 is composed of a conductive metal electrode film. Examples of the material of the upper electrode layer 140 include the same materials as those of the above-described lower electrode layer 110, copper (Cu), silver (Ag), etc.

When driving the piezoelectric element 100, a control voltage is applied between the lower electrode layer 110 and the upper electrode layer 140. When the control voltage is applied, vibration of the piezoelectric layer 130 is excited by the inverse piezoelectric effect of the piezoelectric layer 130.

The piezoelectric element 100 in FIG. 4A includes the lower electrode layer 110, the orientation control layer 120, the piezoelectric layer 130, and the upper electrode layer 140, but a configuration obtained by adding a substrate to the configuration of FIG. 4A may be used as a piezoelectric element 200.

FIG. 4B is a cross-sectional view schematically showing the configuration of the piezoelectric element 200. In FIG. 4B, for convenience, the same components as those in FIG. 4A are denoted by the same reference characters.

The piezoelectric element 200 includes a substrate 210 and components which are formed on the upper surface of the substrate 210 and are the components shown in FIG. 4A.

The substrate 210 is, for example, a silicon (Si) substrate, an oxide substrate having a NaCl type structure such as MgO, an oxide substrate having a perovskite type structure such as SrTiO₃, LaAlO₃, and NdGaO₃, an oxide substrate having a corundum type structure such as Al₂O₃, an oxide substrate having a spinel type structure such as MgAl₂O₄, an oxide substrate having a rutile type structure such as TiO₂, an oxide substrate having a cubic type crystal structure such as (La, Sr) (Al, Ta)O₃ and yttria-stabilized zirconia (YSZ), or the like. The substrate 210 is formed, for example, by stacking an oxide thin film having a NaCl type crystal structure on the surface of a glass substrate, a ceramic substrate such as an alumina substrate, or a metal substrate such as a stainless steel substrate. The substrate 210 is preferably a Si single-crystal substrate.

An interface layer that grows epitaxially is also disposed on the surface of the substrate 210. Examples of the material of the interface layer include yttria-stabilized zirconia (YSZ), materials having a fluorite type structure such as CeO₂, materials having a NaCl type structure such as MgO, BaO, SrO, TiN, and ZrN, materials having a perovskite type structure such as SrTiO₃, LaAlO₃, (La, Sr)MnO₃, and (La, Sr)Co₃, materials having a spinel type structure such as γ-Al₂O₃ and MgAl₂O₄, etc. The interface layer is composed of, for example, two or more of the above materials, and is specifically CeO₂/YSZ/Si. The material of the interface layer may be SiO₂, or the interface layer may be omitted.

The lower electrode layer 110 is formed on the upper surface of the interface layer which is disposed on the surface of the substrate 210 (or on the upper surface of the substrate 210 if the interface layer is omitted). An adhesion layer that improves the adhesion between the substrate 210 and the lower electrode layer 110 may be disposed therebetween. The material of the adhesion layer is, for example, Ti. The material of the adhesion layer may be W, Ta, Fe, Co, Ni, Cr, or compounds thereof. The adhesion layer may be composed of two or more of these materials. Depending on the adhesion between the substrate 210 and the lower electrode layer 110, the adhesion layer may be omitted.

After the lower electrode layer 110 is formed, the orientation control layer 120, the piezoelectric layer 130, and the upper electrode layer 140 are formed in this order on the upper surface of the lower electrode layer 110 as described with reference to FIG. 4A.

After the piezoelectric element 200 is formed as shown in FIG. 4B, the substrate 210 may be removed by etching or the like. The piezoelectric element 100 shown in FIG. 4A can be obtained by removing the substrate 210 from the piezoelectric element 200.

### EXAMPLES AND COMPARATIVE EXAMPLES

Next, specific configuration examples of the embodiment and the measurement results of a piezoelectric constant d31 and a withstand voltage in each configuration example will be described. In the following, Examples 1 to 11 are described as the specific configuration examples of the embodiment, and Comparative Examples 1 and 2 are described for comparison with the Examples.

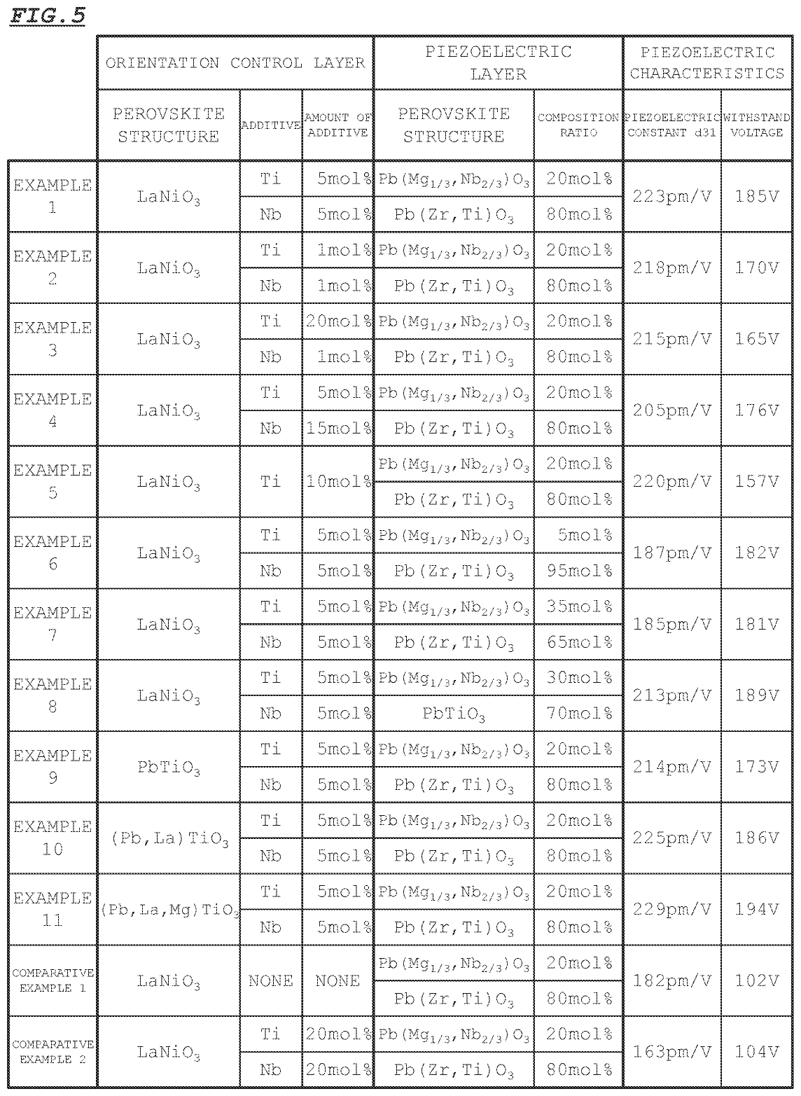

In measurement, in the piezoelectric element 200 having the configuration shown in FIG. 4B, a voltage having a predetermined voltage value was applied between the lower electrode layer 110 and the upper electrode layer 140 to cause piezoelectric strain in the piezoelectric element 200, and the piezoelectric constant d31 and the withstand voltage of the piezoelectric element 200 were measured. FIG. 5 is a table showing the configurations of the orientation control layers 120 and the piezoelectric layers 130 in Examples 1 to 11 and Comparative Examples 1 and 2 and the measurement results thereof. The piezoelectric constant d31 actually has a negative value, but in FIG. 5, the value of the piezoelectric constant d31 is shown as an absolute value as described above.

### Example 1

In Example 1, the substrate 210 was composed of a Si single-crystal substrate oriented in the (100) plane, and the lower electrode layer 110 was composed of Pt oriented in the (111) plane. Before the lower electrode layer 110 was formed, a Ti layer was formed on the surface of the substrate 210 to improve the adhesion between the substrate 210 and the lower electrode layer 110. The upper electrode layer 140 was composed of Au. The orientation control layer 120 was formed so as to have a perovskite structure of LaNiO₃ and be oriented in the (001) plane. The piezoelectric layer 130 was formed so as to have a perovskite structure of Pb(Zr, Ti)O₃ including Pb(Mg_{1/3}, Nb_{2/3})O₃ and be oriented in the (001) plane. Each layer was formed by a sputtering method.

The orientation control layer 120 contained 5 mol % of Ti and 5 mol % of Nb as additives. As for the composition ratio of the piezoelectric layer 130, Pb(Mg_{1/3}, Nb_{2/3})O₃ was set to 20 mol %, and Pb(Zr, Ti)O₃ was set to 80 mol %. The thickness of the orientation control layer 120 was set to about 200 nm, and the thickness of the piezoelectric layer 130 was set to 3 μm.

As shown in FIG. 5, in Example 1, the piezoelectric constant d31 was 223 pm/V, and the withstand voltage was 185 V. In Example 1, a piezoelectric constant d31 of 120 pm/V or higher and a withstand voltage of 150 V or higher and more preferably 180 V or higher were realized. From this, it is confirmed that the MEMS mirrors 1 and 2 having very high deflection angle performance can be realized by using the piezoelectric elements 100 having the same structure as that of the piezoelectric element 200 of Example 1.

### Example 2

In Example 2, compared to Example 1, the amounts of Ti and Nb added to the orientation control layer 120 were each decreased to 1 mol %. The other configuration is the same as in Example 1.

As shown in FIG. 5, in Example 2, the piezoelectric constant d31 was 218 pm/V, and the withstand voltage was 170 V. In Example 2, a piezoelectric constant d31 of 120 pm/V or higher and a withstand voltage of 150 V or higher were realized. From this, it is confirmed that the MEMS mirrors 1 and 2 having high deflection angle performance can be realized by using the piezoelectric elements 100 having the same structure as that of the piezoelectric element 200 of Example 2.

### Example 3

In Example 3, compared to Example 2, the amount of Ti added to the orientation control layer 120 was increased to 20 mol %. The other configuration is the same as in Example 2.

As shown in FIG. 5, in Example 3, the piezoelectric constant d31 was 215 pm/V, and the withstand voltage was 165 V. In Example 3, a piezoelectric constant d31 of 120 pm/V or higher and a withstand voltage of 150 V or higher were realized. From this, it is confirmed that the MEMS mirrors 1 and 2 having high deflection angle performance can be realized by using the piezoelectric elements 100 having the same structure as that of the piezoelectric element 200 of Example 3.

### Example 4

In Example 4, compared to Example 1, the amount of Nb added to the orientation control layer 120 was increased to 15 mol %. The other configuration is the same as in Example 1.

As shown in FIG. 5, in Example 4, the piezoelectric constant d31 was 205 pm/V, and the withstand voltage was 176 V. In Example 4, a piezoelectric constant d31 of 120 pm/V or higher and a withstand voltage of 150 V or higher were realized. From this, it is confirmed that the MEMS mirrors 1 and 2 having high deflection angle performance can be realized by using the piezoelectric elements 100 having the same structure as that of the piezoelectric element 200 of Example 4.

### Example 5

In Example 5, compared to Example 1, only Ti was added to the orientation control layer 120, and the amount of Ti added thereto was set to 10 mol %. The other configuration is the same as in Example 1.

As shown in FIG. 5, in Example 5, the piezoelectric constant d31 was 220 pm/V, and the withstand voltage was 157 V. In Example 5, a piezoelectric constant d31 of 120 pm/V or higher and a withstand voltage of 150 V or higher were realized. From this, it is confirmed that the MEMS mirrors 1 and 2 having high deflection angle performance can be realized by using the piezoelectric elements 100 having the same structure as that of the piezoelectric element 200 of Example 5.

### Example 6

In Example 6, compared to Example 1, the composition ratio of Pb(Mg_{1/3}, Nb_{2/3})O₃ in the piezoelectric layer 130 was decreased to 5 mol %, and the composition ratio of Pb(Zr, Ti)O₃ in the piezoelectric layer 130 was increased to 95 mol %. The other configuration is the same as in Example 1.

As shown in FIG. 5, in Example 6, the piezoelectric constant d31 was 187 pm/V, and the withstand voltage was 182 V. In Example 6, a piezoelectric constant d31 of 120 pm/V or higher and a withstand voltage of 150 V or higher and more preferably 180 V or higher were realized. From this, it is confirmed that the MEMS mirrors 1 and 2 having very high deflection angle performance can be realized by using the piezoelectric elements 100 having the same structure as that of the piezoelectric element 200 of Example 6.

### Example 7

In Example 7, compared to Example 1, the composition ratio of Pb(Mg_{1/3}, Nb_{2/3})O₃ in the piezoelectric layer 130 was increased to 35 mol %, and the composition ratio of Pb(Zr, Ti)O₃ in the piezoelectric layer 130 was decreased to 65 mol %. The other configuration is the same as in Example 1.

As shown in FIG. 5, in Example 7, the piezoelectric constant d31 was 185 pm/V, and the withstand voltage was 181 V. In Example 7, a piezoelectric constant d31 of 120 pm/V or higher and a withstand voltage of 150 V or higher and more preferably 180 V or higher were realized. From this, it is confirmed that the MEMS mirrors 1 and 2 having very high deflection angle performance can be realized by using the piezoelectric elements 100 having the same structure as that of the piezoelectric element 200 of Example 7.

### Example 8

In Example 8, compared to Example 1, the perovskite structure of the piezoelectric layer 130 was changed to PbTiO₃, the composition ratio of Pb(Mg_{1/3}, Nb_{2/3})O₃ in the piezoelectric layer 130 was increased to 30 mol %, and the composition ratio of PbTiO₃ in the piezoelectric layer 130 was set to 70 mol %. The other configuration is the same as in Example 1.

As shown in FIG. 5, in Example 8, the piezoelectric constant d31 was 213 pm/V, and the withstand voltage was 189 V. In Example 8, a piezoelectric constant d31 of 120 pm/V or higher and a withstand voltage of 150 V or higher and more preferably 180 V or higher were realized. From this, it is confirmed that the MEMS mirrors 1 and 2 having very high deflection angle performance can be realized by using the piezoelectric elements 100 having the same structure as that of the piezoelectric element 200 of Example 8.

### Example 9

In Example 9, compared to Example 1, the perovskite structure of the orientation control layer 120 was changed to PbTiO₃. The other configuration is the same as in Example 1.

As shown in FIG. 5, in Example 9, the piezoelectric constant d31 was 214 pm/V, and the withstand voltage was 173 V. In Example 9, a piezoelectric constant d31 of 120 pm/V or higher and a withstand voltage of 150 V or higher were realized. In Example 9, the withstand voltage increased to around 180 V, which is considered to be more preferable in the MEMS mirrors 1 and 2. From this, it is confirmed that the MEMS mirrors 1 and 2 having very high deflection angle performance can be realized by using the piezoelectric elements 100 having the same structure as that of the piezoelectric element 200 of Example 9.

### Example 10

In Example 10, compared to Example 1, the perovskite structure of the orientation control layer 120 was changed to (Pb, La)TiO₃. The other configuration is the same as in Example 1.

As shown in FIG. 5, in Example 10, the piezoelectric constant d31 was 225 pm/V, and the withstand voltage was 186 V. In Example 10, a piezoelectric constant d31 of 120 pm/V or higher and a withstand voltage of 150 V or higher and more preferably 180 V or higher were realized. From this, it is confirmed that the MEMS mirrors 1 and 2 having very high deflection angle performance can be realized by using the piezoelectric elements 100 having the same structure as that of the piezoelectric element 200 of Example 10.

### Example 11

In Example 11, compared to Example 1, the perovskite structure of the orientation control layer 120 was changed to (Pb, La, Mg)TiO₃. The other configuration is the same as in Example 1.

As shown in FIG. 5, in Example 11, the piezoelectric constant d31 was 229 pm/V, and the withstand voltage was 194 V. In Example 11, a piezoelectric constant d31 of 120 pm/V or higher and a withstand voltage of 150 V or higher and more preferably 180 V or higher were realized. From this, it is confirmed that the MEMS mirrors 1 and 2 having very high deflection angle performance can be realized by using the piezoelectric elements 100 having the same structure as that of the piezoelectric element 200 of Example 11.

### Comparative Example 1

In Comparative Example 1, compared to Example 1, no additive was added to the orientation control layer 120. The other configuration is the same as in Example 1.

As shown in FIG. 5, in Comparative Example 1, the piezoelectric constant d31 was 182 pm/V, and the withstand voltage was 102 V. In Comparative Example 1, a piezoelectric constant d31 of 120 pm/V or higher was realized, but a withstand voltage of 150 V or higher was not realized. From this, it can be said that when the piezoelectric elements 100 having the same structure as that of the piezoelectric element 200 of Comparative Example 1 are used, the deflection angle performance of the MEMS mirrors 1 and 2 is decreased as compared to that in the case where the piezoelectric elements 100 having the structures of Examples 1 to 11 are used.

In Example 1, compared to Comparative Example 1, the piezoelectric constant d31 and the withstand voltage are significantly improved. From this, it is confirmed that the piezoelectric constant d31 and the withstand voltage of the piezoelectric element 200 can be significantly improved by adding Ti and Nb to the orientation control layer 120.

### Comparative Example 2

In Comparative Example 2, compared to Example 1, the amounts of Ti and Nb added to the orientation control layer 120 were each increased to 20 mol %. The other configuration is the same as in Example 1.

As shown in FIG. 5, in Comparative Example 2, the piezoelectric constant d31 was 163 pm/V, and the withstand voltage was 104 V. In Comparative Example 2, a piezoelectric constant d31 of 120 pm/V or higher was realized, but a withstand voltage of 150 V or higher was not realized.

In Comparative Example 2, compared to Example 1, the piezoelectric constant d31 and the withstand voltage were significantly decreased. Accordingly, it is confirmed that even when the perovskite structures of the orientation control layer 120 and the piezoelectric layer 130 and the type of the additive of the orientation control layer 120, and the composition ratios of Pb(Mg_{1/3}, Nb_{2/3})O₃ and Pb(Zr, Ti)O₃ in the piezoelectric layer 130 are the same, if the amounts of Ti and Nb added to the orientation control layer 120 are excessively large, the piezoelectric constant d31 and the withstand voltage are decreased. Therefore, it can be said that when the perovskite structures of the orientation control layer 120 and the piezoelectric layer 130, the type of the additive of the orientation control layer 120, and the composition and the composition ratio of the piezoelectric layer 130 are the same as those of Examples 1 to 8, the amount of Ti added to the orientation control layer 120 is preferably about 1 to 20 mol %, and the amount of Nb added to the orientation control layer 120 is preferably about 1 to 15 mol %.

In the above Examples and Comparative Examples, the orientation control layer 120 and the piezoelectric layer 130 were oriented in the (001) plane. Here, when the orientation control layer 120 and the piezoelectric layer 130 are cubic crystals, the orientation in the (100) plane and the orientation in the (001) plane are completely equivalent to each other, and also, when the orientation control layer 120 and the piezoelectric layer 130 are nearly cubic crystals (pseudo-cubic crystals), the orientation in the (100) plane and the orientation in the (001) plane are nearly equivalent to each other. Therefore, even when the orientation control layer 120 and the piezoelectric layer 130 are oriented in the (100) plane, it is expected that measurement results similar to those of the above Examples are obtained by causing the orientation control layer 120 to contain a component that is the same as a component of the piezoelectric layer 130. In this case as well, the orientation control layer 120 and the piezoelectric layer 130 preferably have the same perovskite structures as those of Examples 1 to 11, and the composition ratio of the piezoelectric layer 130 and the amounts of Ti and Nb added to the orientation control layer 120 need to be adjusted to be in appropriate ranges that can effectively improve the piezoelectric constant d31 and the withstand voltage.

### Effects of Embodiment and Examples

According to the present embodiment and the Examples, the following effects are achieved.

Since the orientation control layer 120 contains a part of the components forming the piezoelectric layer 130 (at least one of Ti and Nb) as an additive, the orientation of the piezoelectric layer 130 is easily aligned with the (001) plane or the (100) plane in which the orientation control layer 120 is oriented, so that the piezoelectric layer 130 can be more stably oriented in the (001) plane or the (100) plane. Accordingly, the piezoelectric constant d31 and the withstand voltage of each piezoelectric element 100 or 200 can be increased.

As shown in the experimental results of FIG. 5, especially when the perovskite structure of the orientation control layer 120 is PbTiO₃, (Pb, La)TiO₃, (Pb, La, Mg)TiO₃, or LaNiO₃, the piezoelectric constant d31 and the withstand voltage of the piezoelectric element 200 can be more effectively increased. Specifically, when the perovskite structure of the orientation control layer 120 is LaNiO₃, (Pb, La)TiO₃, or (Pb, La, Mg)TiO₃ as shown in Examples 1, 10, and 11, for example, by applying the conditions of Examples 1, 10, and 11, the piezoelectric constant d31 can be increased to 150 pm/V or higher, and the withstand voltage can be increased to 180 V or higher. In addition, when the perovskite structure of the orientation control layer 120 is PbTiO₃ as shown in Example 9, for example, by applying the conditions of Example 9, the piezoelectric constant d31 can be increased to 150 pm/V or higher, and the withstand voltage can be increased to around 180 V.

As shown in the experimental results of FIG. 5, when the orientation control layer 120 contains at least one of Ti and Nb as an additive, the piezoelectric constant d31 and the withstand voltage of the piezoelectric element 200 can be effectively increased. Specifically, the piezoelectric constant d31 and the withstand voltage of the piezoelectric element 200 can be increased to be in the ranges of values required for MEMS mirrors (piezoelectric constant d31: 120 pm/V or higher, withstand voltage: 150 V or higher).

In Examples 1 to 11 described above, the piezoelectric layer 130 was formed on the upper surface of the orientation control layer 120 by the sputtering method. From the measurement results of Examples 1 to 11 described above, it is confirmed that when the sputtering method is used as the method for forming the piezoelectric layer 130, the piezoelectric constant d31 and the withstand voltage of the piezoelectric element 200 can be increased.

Since each MEMS mirror 1 or 2 includes the piezoelectric elements 100 or 200 having high piezoelectric constants d31 and withstand voltages as driving sources, the deflection angle of the mirror 62 when a constant voltage is applied can be increased, and the mirror 62 can be driven at a higher driving voltage. Therefore, the mirror 62 can be driven at a larger deflection angle, and the deflection angle characteristics of each MEMS mirror 1 or 2 can be significantly enhanced.

<Modifications>

The configurations of the MEMS mirrors 1 and 2 and the piezoelectric elements 100 and 200 can be modified in various ways other than the configurations shown in the above embodiment and Examples.

For example, in the above embodiment and Examples, the upper electrode layer 140 is formed on the upper surface of the piezoelectric layer 130. However, the present invention is not limited thereto, and a layer of titanium (Ti), tungsten (W), or the like may be formed between the piezoelectric layer 130 and the upper electrode layer 140 such that the adhesion of the upper electrode layer 140 to the piezoelectric layer 130 is enhanced.

In the above embodiment and Examples, when the perovskite structure of the piezoelectric layer 130 is Pb(Zr, Ti)O₃, since the piezoelectric layer 130 contains zirconium (Zr), the orientation control layer 120 may contain Zr which is a part of the components forming the piezoelectric layer 130, as an additive. In addition, since the piezoelectric layer 130 contains magnesium (Mg), the orientation control layer 120 may contain Mg which is a part of the components forming the piezoelectric layer 130, as an additive. In this case as well, it is expected that the orientation of the orientation control layer 120 and the orientation of the piezoelectric layer 130 are matched to each other, so that the piezoelectric constant d31 can be increased.

In the above Examples, the orientation control layer 120 contains, as an additive, both Ti and Nb (Examples 1 to 4 and 6 to 11) or only Ti (Example 5) as a part of the components forming the piezoelectric layer 130, but the additive is not limited thereto. For example, the orientation control layer 120 may contain, as an additive, only Nb as a part of the components forming the piezoelectric layer 130. In this case as well, it is easier for the piezoelectric layer 130 to grow in an orientation along the orientation of the orientation control layer 120, starting from Nb, so that the piezoelectric constants d31 of the piezoelectric elements 100 and 200 can be increased.

In the above embodiment and Examples, the orientation control layer 120 and the piezoelectric layer 130 are each formed by the sputtering method, but the methods for forming the orientation control layer 120 and the piezoelectric layer 130 are not limited thereto. For example, the orientation control layer 120 and the piezoelectric layer 130 may each be formed by a thin film formation method such as a CSD method, a pulsed laser deposition (PLD) method, a chemical vapor deposition (CVD) method, a sol-gel method, or an aerosol deposition (AD) method so as to be oriented in the (001) plane or the (100) plane. In these cases as well, since the orientation control layer 120 contains a part of the components forming the piezoelectric layer 130, the orientation of the piezoelectric layer 130 can be more stably matched to the orientation of the orientation control layer 120.

In the above embodiment and Examples, the perovskite structure of the orientation control layer 120 is PbTiO₃, (Pb, La)TiO₃, (Pb, La, Mg)TiO₃, or LaNiO₃. However, the perovskite structure of the orientation control layer 120 may have a composition other than these compositions.

In the above embodiment, each piezoelectric element 100 or 200 is used as a part of a MEMS mirror. However, each piezoelectric element 100 or 200 may be incorporated into another device such as a MEMS element, a mirror actuator, a wavelength variable filter, and an inkjet head.

In the above embodiment, the values required for the piezoelectric constant d31 and the withstand voltage when the piezoelectric elements 100 are used for the MEMS mirrors 1 and 2 are shown. However, the values required for the piezoelectric constant d31 and the withstand voltage are not necessarily limited thereto, and may be changed as appropriate for each device into which the piezoelectric elements 100 or 200 are incorporated. Also, in the case where the piezoelectric elements 100 or 200 are incorporated into a device other than the MEMS mirrors 1 and 2, by causing the orientation control layer 120 to contain a part of the components forming the piezoelectric layer 130, the piezoelectric performance of the piezoelectric elements 100 or 200 can be enhanced. Accordingly, the performance of the device into which the piezoelectric elements 100 or 200 are incorporated can be significantly enhanced.

In addition to the above, various modifications can be made as appropriate to the embodiment of the present invention, without departing from the scope of the technological idea defined by the claims.

What is claimed is:

1. A piezoelectric element comprising:
a lower electrode layer;
an upper electrode layer;
an orientation control layer disposed between the lower electrode layer and the upper electrode layer; and
a piezoelectric layer formed on an upper surface of the orientation control layer, wherein
the piezoelectric layer is oriented in a (001) plane or a (100) plane and has a perovskite structure including Pb(Mg_{1/3}, Nb_{2/3})O₃, and
the orientation control layer has a perovskite structure, is oriented in the (001) plane or the (100) plane, and contains a part of components forming the piezoelectric layer, as an additive.

2. The piezoelectric element according to claim 1, wherein the perovskite structure of the orientation control layer is PbTiO₃, (Pb, La)TiO₃, (Pb, La, Mg)TiO₃, or LaNiO₃.

3. The piezoelectric element according to claim 1, wherein the perovskite structure of the piezoelectric layer is Pb(Zr, Ti)O₃ or PbTiO₃.

4. The piezoelectric element according to claim 3, wherein the orientation control layer contains at least one of Ti and Nb as an additive.

5. A MEMS mirror comprising:
a piezoelectric element;
a movable part configured to be movable when the piezoelectric element is driven; and
a mirror installed at the movable part, wherein
the piezoelectric element includes
a lower electrode layer,
an upper electrode layer,
an orientation control layer disposed between the lower electrode layer and the upper electrode layer, and
a piezoelectric layer formed on an upper surface of the orientation control layer,
the piezoelectric layer is oriented in a (001) plane or a (100) plane and has a perovskite structure including Pb(Mg_{1/3}, Nb_{2/3})O₃, and
the orientation control layer has a perovskite structure, is oriented in the (001) plane or the (100) plane, and contains a part of components forming the piezoelectric layer, as an additive.

6. The MEMS mirror according to claim 5, wherein the perovskite structure of the orientation control layer is PbTiO₃, (Pb, La) TiO₃, (Pb, La, Mg) TiO₃, or LaNiO₃.

7. The MEMS mirror according to claim 5, wherein the perovskite structure of the piezoelectric layer is Pb(Zr, Ti)O₃ or PbTiO₃.

8. The MEMS mirror according to claim 7, wherein the orientation control layer contains at least one of Ti and Nb as an additive.
